(19) United States
(12) Patent Application Publication
(10) Pub. No.: US 2008/0128764 A1
(43) Pub. Date: Jun. 5, 2008

(54) Semiconductor substrate including a plurality of insulating regions, semiconductor device having the same, and method of manufacturing the device

(75) Inventor: Won-chang Lee, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/998,188

(22) Filed: Nov. 29, 2007

(30) Foreign Application Priority Data
Nov. 30, 2006 (KR) 10-2006-0119853

(51) Int. Cl. H01L 29/78; H01L 21/04

(52) U.S. Cl. 257/288; 257/635; 438/787; 438/294; 257/E29.255; 257/E21.04

(57) ABSTRACT

A semiconductor substrate including a plurality of insulating elements formed of an insulating material in the substrate, a semiconductor device having the same, and methods of manufacturing the substrate and the device are provided. The semiconductor device includes isolation regions formed in a semiconductor substrate, transistors formed on the semiconductor substrate, source/drain regions formed between the transistors and the isolation regions in the semiconductor substrate, and a plurality of the elements formed of insulating material being formed within the semiconductor substrate a predetermined distance beneath a top surface of the substrate.

### CROSS REFERENCE TO RELATED APPLICATION

This application claims priority from Korean Patent Application No. 10-2006-0119853 filed on Nov. 30, 2006, in the Korean Intellectual Property Office, the contents of which are incorporated herein by reference in their entirety.

### BACKGROUND OF THE INVENTION

1. Field of the Invention

The present invention relates to a semiconductor substrate structure and a manufacturing method for the same. More particularly, the present invention relates to a silicon-on-insulator (SOI) semiconductor substrate and method of manufacturing the same.

2. Description of the Related Art

SOI substrates are among the most promising next-generation semiconductor substrates. The SOI substrate has little leakage current and is considered to have highest practicality among the next-generation semiconductor substrates since it allows semiconductor devices to have low power consumption and high speed.

An SOI substrate and a semiconductor device manufactured using the SOI substrate are shown in detail in the figures.

FIG. 1 is a sectional view illustrating a semiconductor device structure manufactured using the conventional SOI substrate.

Referring to FIG. 1, the semiconductor device manufactured using the SOI substrate includes a lower silicon substrate region 10, an insulating layer 80 formed on the lower silicon substrate region 10, and an upper silicon substrate region 15 formed on the insulating layer 80.

The upper silicon substrate region 15 and the lower silicon substrate 10 are electrically isolated by the insulating layer 80, and the upper silicon substrate region 15 is isolated by the isolation region 20. Since the SOI substrate has such a structure where the upper silicon substrate region 15, where active regions are formed, is floating, some side effects are introduced. Specifically, when a semiconductor device is manufactured using an SOI substrate, the upper silicon substrate region 15 needs to be formed to be as small as possible. As a result, side effects are introduced by the small upper silicon substrate region 15

For example, a kink effect occurs due to carriers (electrons and holes) in the upper silicon substrate region 15, which causes changes of threshold voltage (Vth) and unstable currents due to gate voltage changes. Also, a Parasitic Bipolar Transistor (PBT) effect occurs due to the malfunction caused by a pseudo-bipolar transistor formed by the carrier accumulated region and source/drain region 40a and 40b of a transistor. In addition, since the insulating layer 80 is inferior to silicon in heat transfer characteristics, the performance of the semiconductor device can be degraded due to the insufficient discharge of heat generated from the upper silicon substrate 15. These negative effects occur due to the fact that the upper silicon substrate region 15 on the SOI substrate is isolated, that is, it floats.

Therefore, when manufacturing a semiconductor device using an SOI semiconductor substrate, a method is required to prevent or remedy the carrier accumulation on the upper silicon substrate region 15 and the degradation.

### SUMMARY OF THE INVENTION

The present invention provides an SOI semiconductor substrate and an SOI semiconductor device whose carriers and heat generated in an upper silicon substrate region can be discharged into a lower silicon substrate region.

The present invention also provides a method of manufacturing a semiconductor substrate and a semiconductor device whose carriers and heat can be discharged into a lower silicon substrate region by using an SOI substrate.

According to a first aspect, the present invention is directed to a semiconductor substrate comprising a plurality of elements formed of insulating material, the plurality of elements being formed within the semiconductor substrate a predetermined distance beneath a top surface of the semiconductor substrate.

According to another aspect, the present invention is directed to a semiconductor device comprising isolation regions formed in a semiconductor substrate, transistors formed on the semiconductor substrate, source/drain regions formed between the transistors and the isolation regions in the semiconductor substrate, and a plurality of elements formed of insulating material being formed within the semiconductor substrate a predetermined distance beneath a top surface of the semiconductor substrate.

According to another aspect, the invention is directed to a method of fabricating a semiconductor substrate, the method comprising, providing a semiconductor substrate, and forming a plurality of elements formed of insulating material within the semiconductor substrate a predetermined distance beneath a top surface of the semiconductor substrate.

According to another aspect, the invention is directed to a method of fabricating a semiconductor device, the method comprising, forming isolation regions in a semiconductor substrate, forming well regions in the semiconductor substrate, forming transistors on the semiconductor substrate, forming source/drain regions between the transistors and the isolation regions in the semiconductor substrate, forming a plurality of elements of insulating material within the semiconductor substrate a predetermined distance beneath a top surface of the semiconductor substrate.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a sectional view illustrating a conventional semiconductor device manufactured using an SOI substrate.

FIGS. 2A through 3C are sectional views illustrating semiconductor substrates according to various exemplary embodiments of the present invention.

FIGS. 4A through 5C are sectional views illustrating semiconductor devices according to various exemplary embodiments of the present invention.

FIGS. 6A through 6H are sectional views illustrating semiconductor substrates and manufacturing methods thereof according to an exemplary embodiment of the present invention.

FIGS. 7A through 7C are sectional views illustrating manufacturing method of semiconductor substrates including insulating grains according to an exemplary embodiment of the present invention.

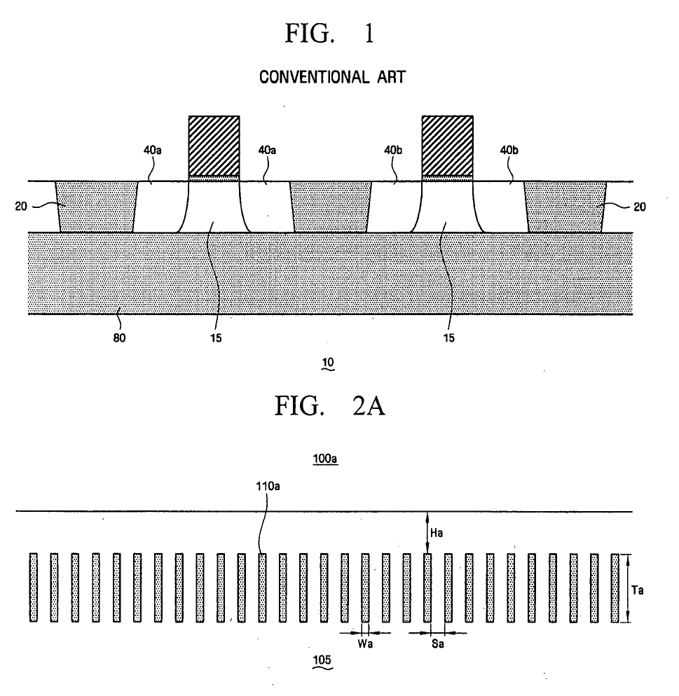

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this description will be thorough and complete and will fully convey the invention to those skilled in the art, and the present invention will only be defined by the appended claims. In the drawings, the shape and thickness of layers and regions are exaggerated or reduced for clarity.

Also, exemplary embodiments of the present invention will be described by referring to ideal figures of the present invention, sectional views and/or simplified diagrams. The shape of the figures can be changed due to fabrication technologies and/or allowable errors. Therefore, the present invention should not be construed as being limited to the embodiments set forth herein, but include variations of the shape which is formed according to the fabricating process. Therefore, regions shown in the figures are illustrated in schematic forms, and the shapes of the illustrated regions in the figures are presented simply by way of illustration and not as a limitation.

Hereinafter, semiconductor substrates according to various exemplary embodiments of the present invention will be described with reference to drawings.

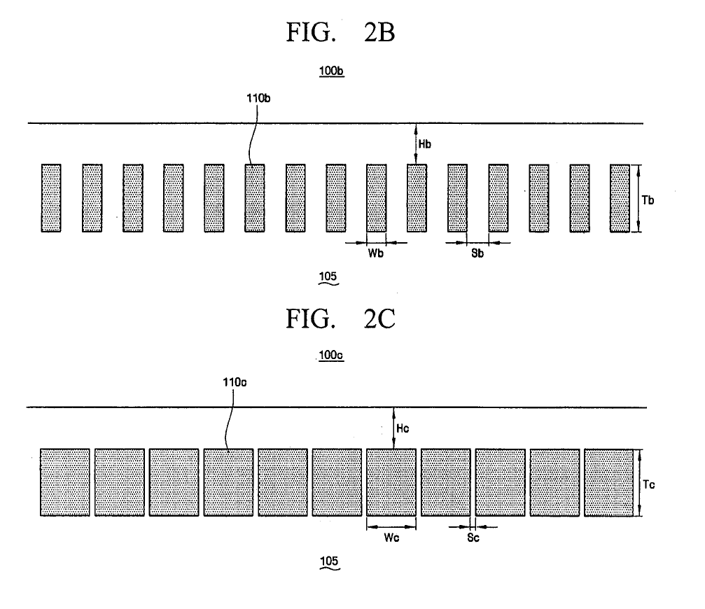

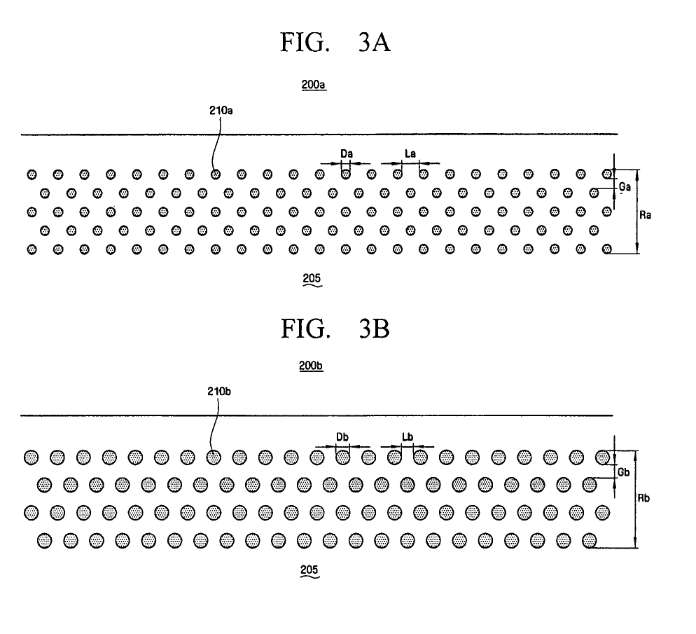

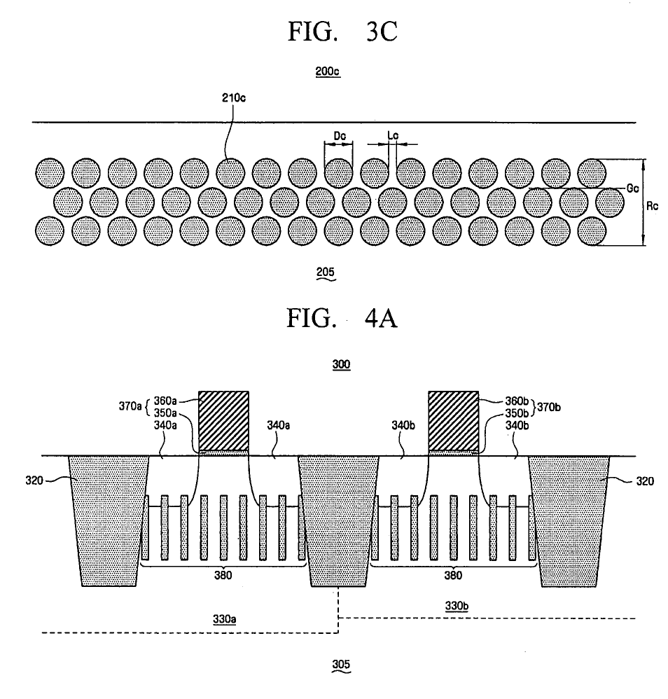

FIGS. 2A through 3C are sectional views illustrating semiconductor substrates according to various exemplary embodiments of the present invention.

Referring to FIG. 2A, according to the first exemplary embodiment of the present invention, a semiconductor substrate 100a includes multiple insulating pillars 110a formed in an inner part of the substrate 105. In the present exemplary embodiment, the insulating pillars 110a may be formed in the location where an insulating layer is formed in an SOI substrate. An active region of a semiconductor device may be formed in an area Ha between the surface of the semiconductor substrate 100a and the insulating pillars 110a. The semiconductor substrate 100a based on the first exemplary embodiment of the present invention allows discharge of carriers and heat generated in the active region through the space between the insulating pillars 110a. As a result, it prevents the effects caused by the floating active regions in an SOI semiconductor substrate.

The insulating pillars 110a can be formed such that their vertical height Ta is compatible with the vertical thickness of the insulating layer of a general SOI substrate. For example, the vertical height Ta can be about 1 μm to about 10 μm. The insulating layer of the SOI substrate can be made to have different vertical thickness, and specific numbers are not provided since it is a well-known technology.

The horizontal width Wa of the insulating pillars 110a, for example, can be about 10 Å. However, it is considered that the horizontal width Wa of the insulating pillars 110a has little effects on the characteristics of the SOI substrate 100a. The characteristics of the SOI substrate 100a are much more dependent on the space Sa between the insulating pillars 110a than the horizontal width Wa of the insulating pillars 110a. In the present exemplary embodiment, the insulating pillars 110a may be formed such that the space Sa between the pillars 110a is approximately 100 Å. This space is an example to illustrate the present invention, and it can be different depending on the implementation of the invention.

In the present exemplary embodiment, the insulating pillars 110a may be formed such that the spaces Sa between the pillars 110a are larger than the horizontal width Wa of the pillars 110a.

In the present exemplary embodiment, the insulating pillars 110a can be formed of oxide, and more specifically silicon oxide. In the present exemplary embodiment, the insulating pillars 110a are formed of silicon oxide since it allows for simpler processes compared to the process used with other insulating material (for example, silicon nitride) and has outstanding insulation characteristics and heat conductivity. However, the insulating pillars 110a can be formed of silicon nitride.

FIG. 2B is a sectional view illustrating semiconductor substrate 100b according to a second exemplary embodiment of the present invention.

Referring to FIG. 2B, according to the second exemplary embodiment of the present invention, the semiconductor substrate 100b includes multiple insulating pillars 110b formed in an inner part of the substrate 105 such that a horizontal width Wb of the pillars 110b is similar to a space Sb between the pillars 110b. Compared to FIG. 2A, the horizontal width Wb of the insulating pillars 110b is substantially similar to the space Sb between the insulating pillars 110b. If the horizontal width Wb of the insulating pillars 110b is substantially similar to the space Sb between the insulating pillars 110b, a relatively simple design and process can be used to manufacture the semiconductor substrate 100b.

In the second exemplary embodiment of the present invention, the insulating pillars 110b can be formed such that a vertical height Tb of the insulating pillars 110b is compatible with the vertical thickness of an insulating layer of a general SOI substrate.

Referring to FIG. 2C, according to a third exemplary embodiment of the present invention, a semiconductor substrate 100c includes multiple insulating pillars 110c formed in an inner part of the substrate 105 such that a horizontal width Wc of the pillars is larger than a space Sc between the pillars. Compared to FIG. 2A and FIG. 2B, the horizontal width Wc of the insulating pillars 110c is larger than the space Sc between the insulating pillars 110c. Since the larger the horizontal width Wc of the insulating pillars 110c, the more similar the substrate becomes to the basic SOI structure, and it gains the merits of the SOI substrate.

According to the various exemplary embodiments illustrated by the FIGS. 2A through 2C, the semiconductor substrates 100a, 100b and 100c can be formed of any of the shapes and sizes of the insulating pillars 110a, 110b and 110c according to characteristics of the semiconductor device to be manufactured. The major factors to select the type of the semiconductor substrate 100a, 100b and 100c include the integration density of the semiconductor device, the depth of the isolation regions as well as the horizontal width and the space between the isolation regions, and the operating voltage and current of the semiconductor device.

Referring to FIG. 3A, according to the fourth exemplary embodiment of the present invention, a semiconductor substrate 200a includes multiple insulating grains 210a in an inner part of the substrate 205. According to the FIGS. 2A through 2C the insulating pillars 110a, 110b and 110c are formed to obtain effects of an SOI substrate. In the present exemplary embodiment the insulating grains 210a are formed to obtain effects of an SOI substrate. In the present exemplary embodiment, a diameter Da of the insulating grains 210a is smaller than a horizontal interval La between the insulating grains 210a. Although the drawing to illustrate this exemplary embodiment shows that the horizontal interval La between the insulating grains 210a is larger than a vertical interval Ga between the insulating grains 210a, it can be considered as one of the examples. That is, there is no particular relationship between the horizontal interval La and the vertical interval Ga between the insulating grains 210a. The horizontal interval La and the vertical interval Ga between the insulating grains 210a can be determined based on the characteristics of the semiconductor device to be manufactured. According to experiments, when the horizontal interval La is larger than the vertical interval Ga, a relatively simple process can be used and can result in superior characteristics of the semiconductor device.

In the present exemplary embodiment, the insulating grains 210a are formed of silicon oxide since it allows use of a relatively simple process compared to the process used with other insulating material (for example, silicon nitride) and has outstanding insulation characteristics and heat conductivity. However, the insulating grains 210a can be formed of silicon nitride.

Referring to FIG. 3B, according to a fifth exemplary embodiment of the present invention, a semiconductor substrate 200b includes multiple insulating grains 210b formed in an inner part of the substrate 205 such that a diameter Db of the insulating grains 210b has a similar length to the horizontal interval Lb between insulating grains 210b. Compared to FIG. 2A, the diameter Db of the insulating grains 210b has the same length as the horizontal interval Lb between the insulating grains 210b. Also, a vertical interval Gb between the insulating grains 210b can be made so that it can have the same length as the diameter Db or the horizontal interval Lb of the insulating grains 210b. FIG. 3A and its description can be referred for a further description of the embodiment of FIG. 3B.

Referring to FIG. 3C, according to a sixth exemplary embodiment of the present invention, a semiconductor substrate 200c includes multiple insulating grains 210b formed in an inner part of the substrate 205 such that a diameter Dc of insulating grains 210b is larger than a horizontal interval Lc between insulating grains 210b. Compared to the FIGS. 3A and 3C, a diameter Dc of the insulating grains 210b is larger than the horizontal interval Lc between the insulating grains 210b. Although the drawing shows a vertical interval Gc between the insulating grains 210c to be zero, it can be larger than zero and also it can be smaller than zero.

According to the FIGS. 3A through 3C, the depth or thickness Ra, Rb, Rc of the regions where the insulating grains 210a, 210b and 210c are formed can be made such that the depth can match the vertical thickness of an insulating layer of a general SOI substrate or the height Ta, Tb, Tc of the insulating pillars 110a, 110b and 110c illustrated in FIGS. 2A through 2C.

According to the various exemplary embodiments illustrated in the FIGS. 2A through 3C, the semiconductor substrates 100a, 100b, 100c, 200a, 200b and 200c can be formed of a variety of sizes and spaces of the insulating pillars 110a, 110b and 110c or the insulating grains 210a, 210b and 210c. The semiconductor substrates 100a, 100b, 100c, 200a, 200b and 200c based on the various exemplary embodiments of the present invention do not have floating active regions. Therefore, electrons, holes, or heat generated in the active regions can be discharged.

Although the exemplary embodiments of the invention show the insulating pillars 110a, 110b and 110c being formed in a single layer, they can be formed in multiple layers of insulating pillars.

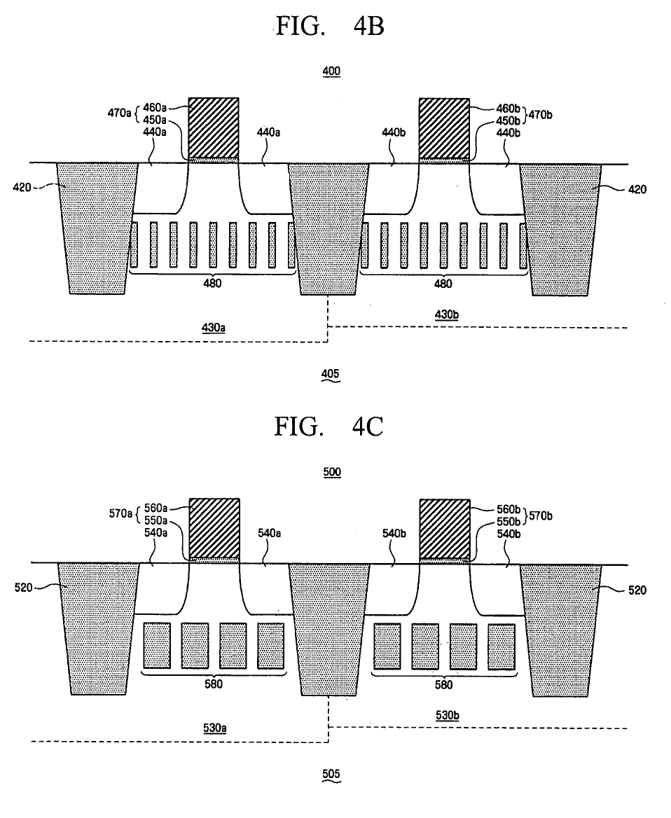

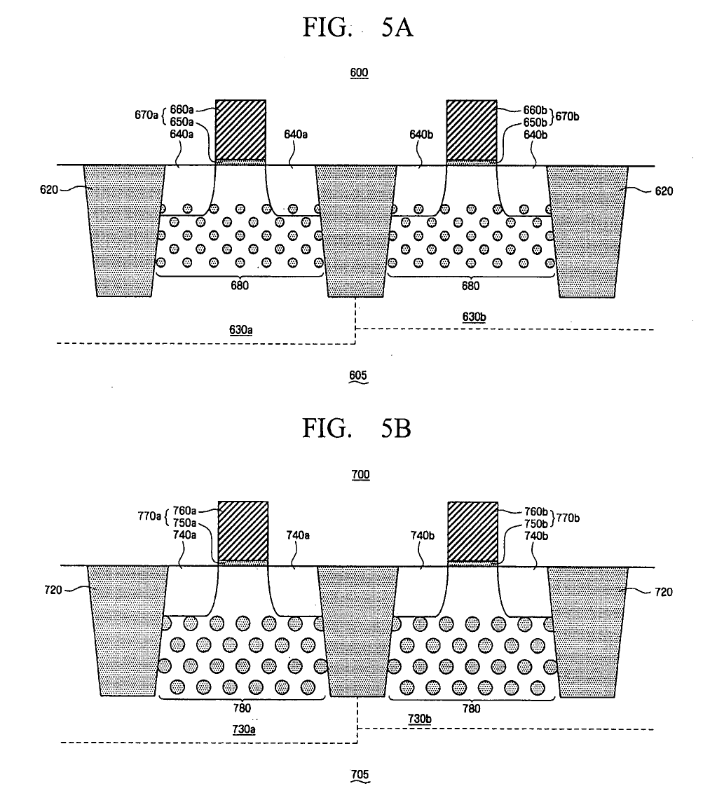

FIGS. 4A through 5C are sectional views illustrating semiconductor devices according to various exemplary embodiments of the present invention.

Referring to FIG. 4A, a semiconductor device 300 based on a first exemplary embodiment of the present invention is composed of isolation regions 320 formed in a substrate 305, well regions 330a, 330b formed under the isolation regions 320, gate patterns 370a and 370b formed on the substrate 305, source/drain regions 340a and 340b formed between the gate patterns 370a and 370b and the isolation regions 320, and insulating pillars 380 formed in the substrate 305.

In the present exemplary embodiment, the substrate 305 can be formed of silicon and the isolation regions 320 can be STI regions.

The well regions 330a and 330b can be formed by implanting N-type ions such as As and P or P-type ions such as B. In the present exemplary embodiment, the P well region 330a is formed to be P-type, and the N well region 330b is formed to be N-type. The P well region 330a can be formed deeper than the N well region 330b, but the invention is not limited to this type of formation. The ion implanting doping density of the each well region 330a, 330b can be determined depending on semiconductor devices to be formed in the structure, as would be well-known.

The gate patterns 370a and 370b include gate insulating layers 350a and 350b formed on the substrate 305, and gate electrodes 360a and 360b formed on the gate insulating layers 350a and 350b. In the present exemplary embodiment, the gate insulating layers 350a and 350b may be formed of silicon oxide, but the gate insulating layers 350a and 350b can be formed of other insulating materials. For example, hafnium oxide or aluminum oxide can be used.

The gate electrodes 360a and 360b are conductive materials and may be formed of doped polycrystalline silicon, metal silicide, or metal. The configuration and fabrication process for the gate electrodes 360a and 360b is well known.

In the present exemplary embodiment, to aid understanding the technical concepts of the present invention, the semiconductor device 300a is illustrated by only showing up to the step of the formation of the gate patterns 370a and 370b.

The source/drain regions 340a and 340b can be formed by implanting impurity ions having opposite polarity to the well regions 330a and 330b. For example, in the P well region 330a, the N type source/drain region 340a can be formed by implanting N type impurity ions, and in the N well region 330b, the P type source/drain 340b can be formed by implanting P type impurity. The ion implanting doping density of the source/drain regions 340a and 340b is well known.

In the present exemplary embodiment, the insulating pillars 380 can be formed of oxide, for example, silicon oxide. The insulating pillars 380 can be overlapped with at least one of the source/drain regions 340a and 340b. In the present exemplary embodiment, the P type source/drain region 340b can be a strained substrate, that is, a SiGe region. In one embodiment, the P type source/drain region 340b is not overlapped with the insulating pillars 380. Moreover, the insulating pillars 380 can not be overlapped with the isolation regions 320.

Referring to FIG. 4B, a semiconductor device 400 based on a second exemplary embodiment of the present invention includes isolation regions 420 formed in a substrate 405, well regions 430a and 430b formed under the isolation regions 420, gate patterns 470a and 470b formed on the substrate 405, source/drain regions 440a and 440b formed between the gate patterns 470a and 470b and the isolation region 420 in the substrate 405, and insulating pillars 480 formed in the substrate 405.

In the present exemplary embodiment, the semiconductor device 400 uses the semiconductor substrate 100b based on the second exemplary embodiment of the present invention described in connection with FIG. 2B, and the insulating pillars 480 are not overlapped with the source/drain regions 440a and 440b. FIG. 4A and its descriptions can be used for other figures.

Referring to FIG. 4C, a semiconductor device 500 based on a third exemplary embodiment of the present invention includes isolation regions 520 formed in a substrate 505, well regions 530a and 530b formed under the isolation regions 520 in the substrate 505, gate patterns 570a and 570b formed on the substrate 505, source/drain regions 540a and 540b formed between the gate patterns 570a and 570b and the isolation regions 520, and insulating pillars 580 formed in the substrate 505.

In the present exemplary embodiment, the semiconductor device 500 uses the semiconductor substrate 100c based on the third exemplary embodiment of the present invention described in connection with FIG. 2C. FIGS. 4A and 4B and their descriptions can be used for other figures.

Referring to FIG. 5A, a semiconductor device 600 based on a fourth exemplary embodiment of the present invention includes isolation regions 620 formed in a substrate 605, well regions 630a and 630b formed under the isolation regions 620, gate patterns 670a and 670b formed on the substrate 605, source/drain regions 640a and 640b formed between the gate patterns 670a and 670b and the isolation regions 620 in the substrate 605, and insulating pillars 680 formed in the substrate 605.

In the present exemplary embodiment, the semiconductor device 600 uses the semiconductor substrate 200a based on the fourth exemplary embodiment of the present invention described in connection with FIG. 3A. FIGS. 2A through 2C and their descriptions can be used for other figures.

Referring to FIG. 5B, a semiconductor device 700 based on a fifth exemplary embodiment of the present invention includes isolation regions 720 formed in a substrate 705, well regions 730a and 730b formed under the isolation regions 720 in the substrate 705, gate patterns 770a and 770b formed on the substrate 705, source/drain regions 740a and 740b formed between the gate patterns 770a and 770b and the isolation regions 720, and plural insulating pillars 780 formed in the substrate 705.

In the present exemplary embodiment, the semiconductor device 700 uses the semiconductor substrate 200b based on the fifth exemplary embodiment of the present invention described in connection with FIG. 3B. FIGS. 4A through 5A and their descriptions can be used for other figures.

Referring to FIG. 5C, a semiconductor device 800 based on a sixth exemplary embodiment of the present invention includes isolation regions 820 formed in a substrate 805, well regions 830a and 830b formed under the isolation regions 820 in the substrate 805, gate patterns 870a and 870b formed on the substrate 805, source/drain regions 840a and 840b formed between the gate patterns 870a and 870b and the isolation regions 820 in the substrate 805, and insulating pillars 880 formed in the substrate 805.

In the present exemplary embodiment, the semiconductor device 800 uses the semiconductor substrate 200c based on the sixth exemplary embodiment of the present invention described in connection with FIG. 3C. FIGS. 4A through 5B and their descriptions can be used for other figures.

The semiconductor substrate manufacturing method based on the present exemplary embodiment of the present invention is described with reference to the drawings.

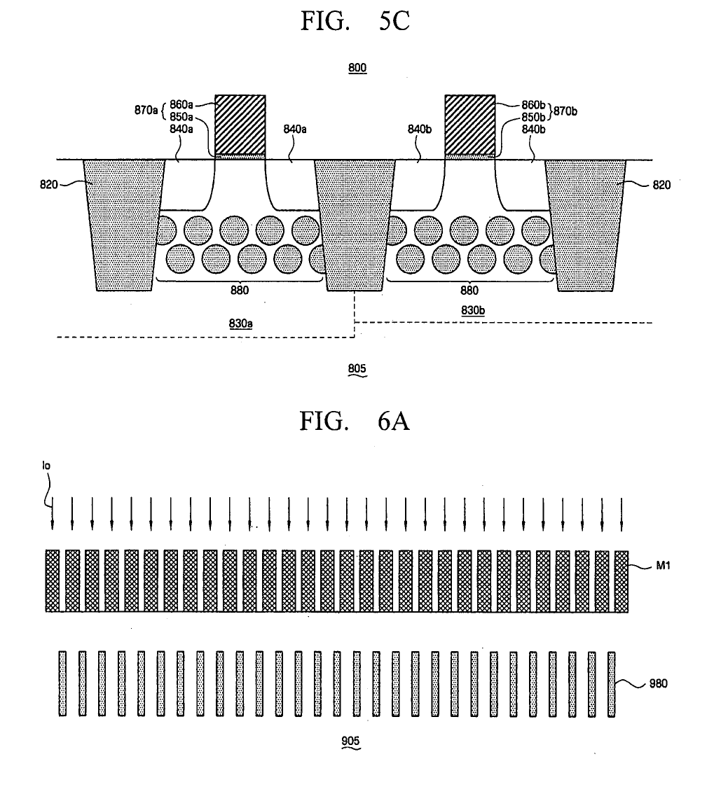

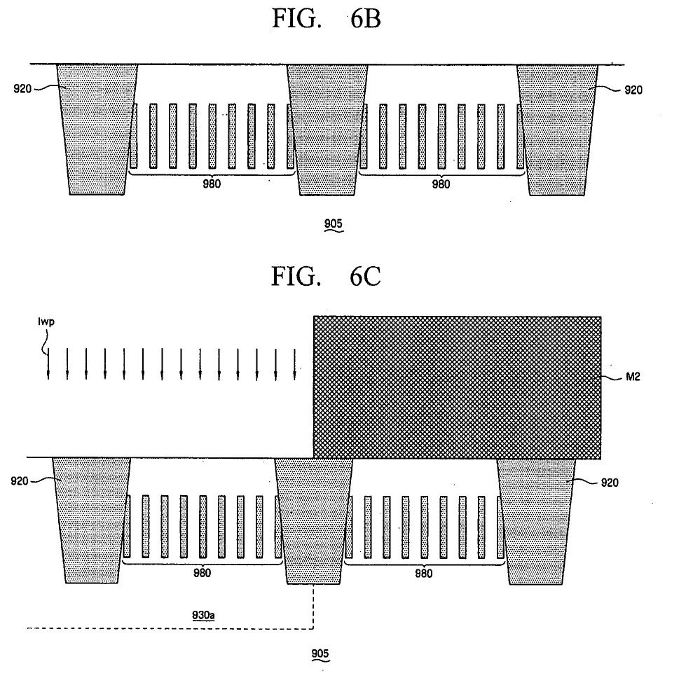

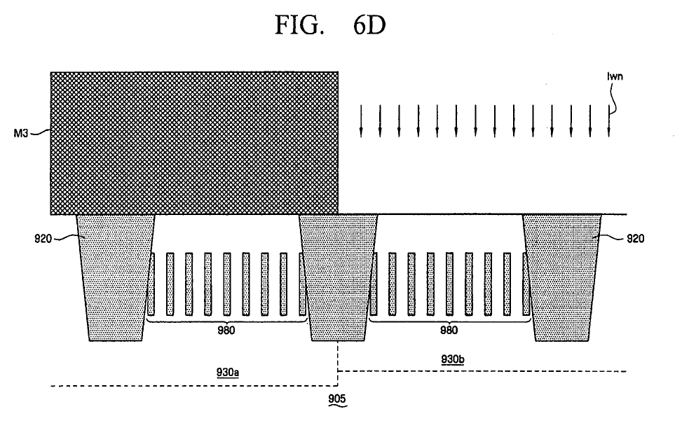

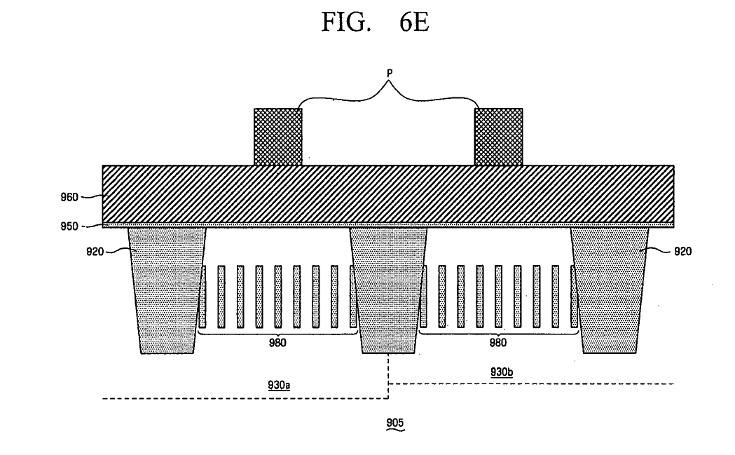

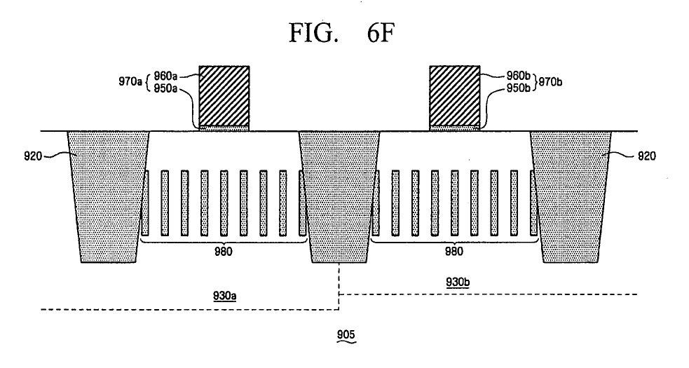

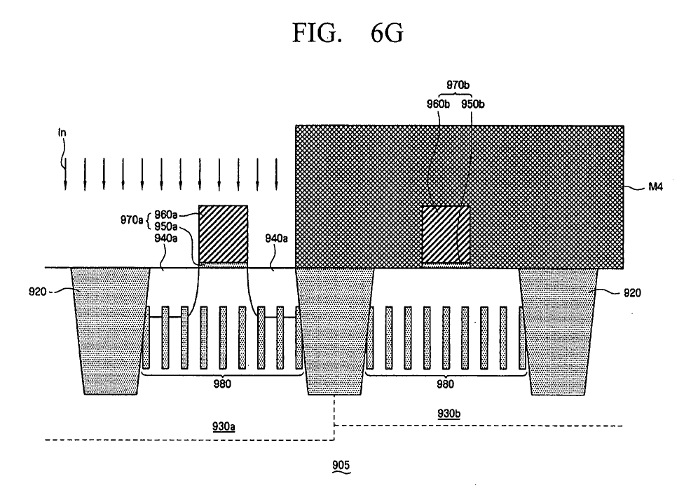

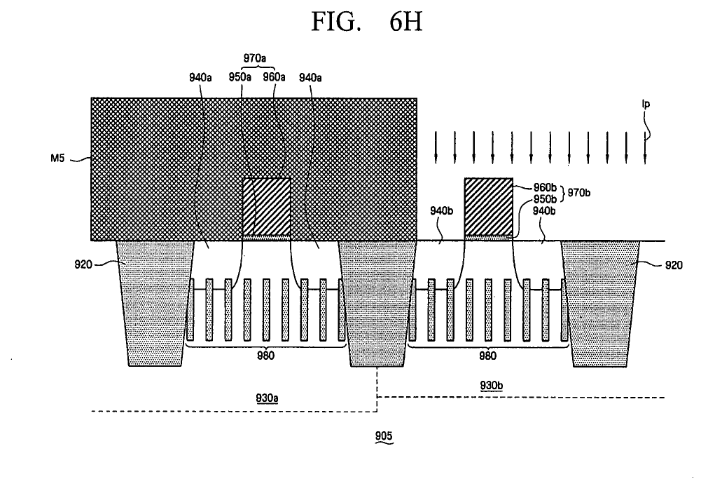

FIGS. 6A through 6H are sectional views illustrating semiconductor substrates and manufacturing methods thereof according to an exemplary embodiment of the present invention.

Referring to FIG. 6A, a first ion implantation mask pattern M1 is formed on a substrate 905, and oxygen ions lo are implanted in the substrate 905.

In the present exemplary embodiment, a photoresist pattern can be used to the first ion implantation mask M1, but the invention is not limited to the photoresist pattern. That is, a material used on the semiconductor substrate 905 during semiconductor manufacturing processes can be used. For example, general insulating materials such as silicon oxide, silicon nitride, and silicon oxynitride can be used, however conducting materials also can be used. The doping density and energy of oxygen ion Io implantation can be determined depending on the location, height, and horizontal width of insulating pillars 980 to be formed. Separation by Implantation of Oxygen (SIMOX), which is one of the methods to manufacture the substrate of SOI structure, can be applied for the ion implantation. For example, ions can be implanted with a doping density of 2×10¹⁸ I/cm², at a temperature of 500° C. Ion implantation methods other than this method are well known.

Referring to FIG. 6B, isolation regions 920 are formed. In the present exemplary embodiment, the isolation regions 920 may be STI regions. The method to form the STI is well known. In the drawing, the isolation regions 920 are shown to be formed deeper than the insulating pillars 980, and this can be considered one example. Since those who perform this invention can form the isolation regions 920 and the insulating pillars 980 in various locations and shapes, the insulating pillars 980 can be formed deeper than the isolation regions 920.

Referring to FIG. 6C, a second ion implantation mask M2 is formed on the substrate 905, and ion Iwp to form a first well region 930a is implanted.

In the present exemplary embodiment, the first well region 930a can be P type, and the second ion implantation mask M2 can be a photoresist pattern. The method to form the first well region 930a is well known.

Referring to FIG. 6D, a third ion implantation mask M3 is formed on the substrate 905, and an ion Iwn to form a second well region 930b is implanted.

In the present exemplary embodiment, the second well region 930b can be N type, and the third ion implantation mask M3 can be a photoresist pattern. The method to form the second well region 930b is well known.

In the present exemplary embodiment, any of the well regions including the first well region 930a and the second well region 930b can be formed first. That is, the second well region 930b can be formed followed by the formation of the first well region 930a. In the drawing, the first well region 930a is shown to be formed deeper than the second well region 930b. However, the second well region 930b can be formed deeper than the first well region 930a.

Referring to FIG. 6E, an insulating layer 950 to form a gate insulating layer and a conductive layer 960 to form a gate electrode are formed, and a photoresist pattern P is formed.

In the present exemplary embodiment, the insulating layer 950 to form the gate insulating layer can be formed of silicon oxide, but other materials, for example, hafnium oxide and aluminum oxide, can be used. The method of forming insulating layer to form the gate insulating layer is well known.

In the present exemplary embodiment, the conductive layer 960 to form the gate electrode can be formed of poly silicon, but it is not limited to the poly silicon. For example, metal silicide or metal can be used. The method of forming the conductive layer 960 to form the gate electrode using these materials is well known.

In the present exemplary embodiment, the photoresist pattern P can be used as an etch mask to form gate patterns. The drawing is exemplary and other materials, other than photoresist pattern P, can be used as the etch mask to form the gate patterns. For example, silicon nitride and silicon oxynitride can be used as a hard mask.

Referring to FIG. 6F, gate patterns 970a, 970b are formed by etching the conductive layer 960 and the insulating layer 950.

In the present exemplary embodiment, the first gate pattern 970a can be an NMOS and the second gate pattern 970b can be a PMOS.

The photoresist pattern P is removed after formation of the gate patterns 970a, 970b.

Referring to FIG. 6G, a fourth ion implantation mask M4 is formed to selectively expose the first gate pattern 970a and a surrounding area of the first gate pattern 970a, and a first source/drain region 940a is formed by implanting ion In.

In the present exemplary embodiment, the selectively exposed gate pattern 970a can be an NMOS, and the surrounding area can be an NMOS region. That is, the implanted ion In can be N type impurity, and can be As or P ion for example.

Referring to FIG. 6H, a fifth ion implantation mask M5 is formed to selectively expose the second gate pattern 970b and a surrounding area of the second gate pattern 970b, and a second source/drain region 940b is formed by implanting ion Ip.

In the present exemplary embodiment, the selectively exposed gate pattern 970b can be PMOS and the surrounding area can be a PMOS region. That is, the implanted ion Ip can be a P-type impurity, and can be a boron B ion, for example.

Next, the fifth ion implantation mask M5 is removed. Then, as shown in FIG. 4A, the semiconductor device 300 based on the first exemplary embodiment of the present invention is complete.

The semiconductor substrates 100a, 100b and 100c based on the various exemplary embodiments of the present invention can be manufactured by adjusting the shape of the first ion implantation mask M1, as shown in FIG. 6A, and the implantation conditions.

Insulating pillars 110a, 110b and 110c can be formed by applying many levels of ion implantation energy from high to low levels of energy. Insulating grains 210a, 210b and 210c can be formed by applying a few levels of ion implantation energy from high to low levels of energy. For example, when forming the insulating pillars 110a, 110b and 110c, since the insulating pillars 110a, 110b and 110c are analogically formed, the insulating pillars 110a, 110b and 110c can be formed by adjusting the ion implantation energy or by gradually reducing or increasing the ion implantation energy during the ion implantation process. When forming the insulating grains 210a, 210b and 210c, the insulating grains 210a, 210b and 210c can be formed by adjusting the ion implantation energy to several levels, which are relatively fewer levels than the levels used to form the insulating pillars 110a, 110b and 110c.

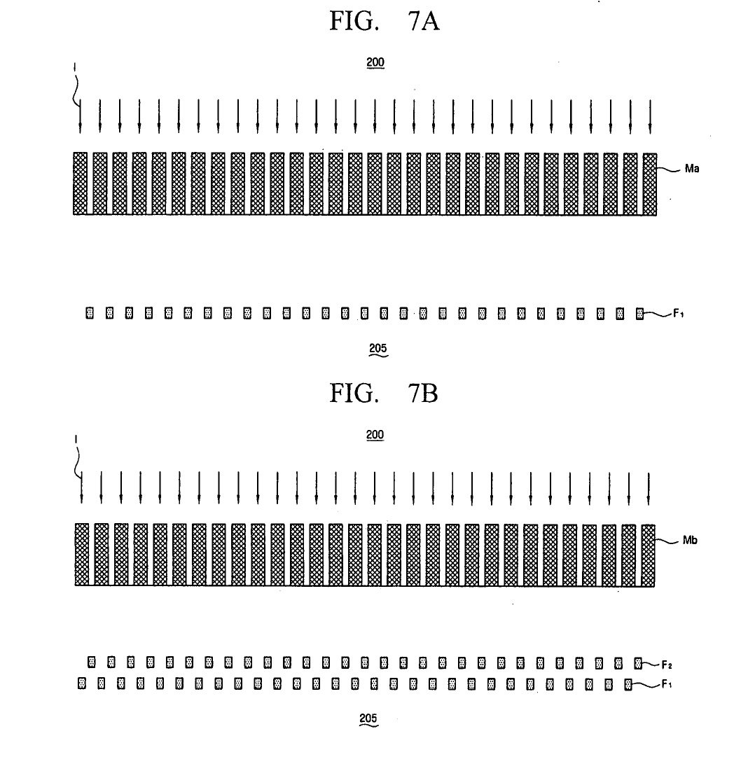

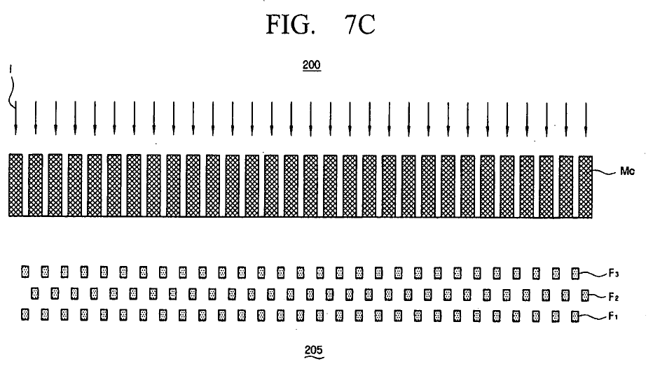

FIGS. 7A through 7C are sectional views illustrating a method of manufacturing semiconductor substrates including insulating grains according to exemplary embodiments of the present invention.

Referring to FIG. 7A, according to the method to manufacture the semiconductor substrate 200 based on another exemplary embodiment of the present invention, first, a first ion implantation mask Ma is formed on a substrate 205 and a first insulating grains layer F1 is formed by implanting ion I.

In the present exemplary embodiment, the substrate 200 can be silicon, and ion I can be an oxygen ion.

In the present exemplary embodiment, the first ion implantation mask Ma, for example, can be formed of photoresist. However, silicon oxide, silicon nitride, silicon oxynitride, and other insulating layers can be used to form the first ion implantation mask Ma.

The first insulating grains layer F1 can be formed in the lowest layer of the grain layers, but is not limited to the lowest layer.

In the drawing, the first insulating grains layer F1 is shown as rectangular to indicate that a heat treatment process, which is generally performed after ion implantation, has not been performed. The heat treatment process to distribute implanted ions can be finally performed after formation of the several insulating grains layers.

Referring to FIG. 7B, a second ion implantation mask Mb is formed on the substrate 200 and a second the insulating grains layer F2 is formed.

In the drawing, the second ion implantation mask Mb and the first ion implantation mask Ma have different shapes, and the insulating grains F1 and F2 are formed in different locations. The drawing, which is exemplary, indicates that the locations of the two layers of the insulating grains F1 and F2 can be different. As another example, the second insulating grains layer F2 can be formed by not forming the second ion implantation mask Mb and using the first ion implantation mask Ma to implant ion I with different ion implantation energy. The second insulating grains layer F2 can be formed by implanting ions at a lower ion implantation energy than that of the first insulating grains layer F1, but is not limited to that particular implantation energy.

Referring to FIG. 7C, a third ion implantation mask Mc is formed on the substrate 200 and a third insulating grains layer F3 is formed.

In the present exemplary embodiment, the third ion implantation mask Mc and the first ion implantation mask Ma can have the same shape. However, it is not limited to that shape and the third ion implantation mask Mc and the second ion implantation mask Ma can have the same shape.

The process described above can be repeated as needed to form the insulating grain layers F1, F2 and F3 with appropriate widths.

After the insulating grain layers F1, F2 and F3 are formed, the semiconductor substrate 200 including the insulating grains 210 can be completed by performing heat treatment to oxidize the insulating grain layers F1, F2 and F3. In the present exemplary embodiment, the heat treatment process can be performed at the temperature of about 400° C.

While the present invention has been particularly shown and described with reference to exemplary embodiments thereof, it will be apparent to those skilled in the art that the scope of the invention is given by the appended claims, rather than the preceding description, and all variations and equivalents which fall within the range of the claims are intended to be embraced therein. Therefore, it should be understood that the above embodiments are not limitative, but illustrative in all aspects.

As described above, since the semiconductor device manufactured by using the semiconductor substrate based on the exemplary embodiments of the present invention discharges the carriers and heat generated in the active region through the substrate, it has stable operational characteristics because of the prevention of the carrier accumulation in active region and degradation.

What is claimed is:

1. A semiconductor substrate comprising:
a plurality of elements formed of insulating material, the plurality of elements being formed within the semiconductor substrate a predetermined distance beneath a top surface of the semiconductor substrate.

2. The semiconductor substrate of claim 1, wherein the elements are spaced apart periodically in a horizontal dimension.

3. The semiconductor substrate of claim 1, wherein the elements have a multilayered structure.

4. The semiconductor substrate of claim 3, wherein the elements are spaced apart periodically in a vertical dimension.

5. The semiconductor substrate of claim 1, wherein the elements are in a pillar shape.

6. The semiconductor substrate of claim 1, wherein the elements are in a grain shape.

7. The semiconductor substrate of claim 1, wherein the elements comprise silicon oxide.

8. The semiconductor substrate of claim 1, wherein a vertical height of the elements is 1 μm to about 10 μm.

9. A semiconductor device comprising:
isolation regions formed in a semiconductor substrate;
transistors formed on the semiconductor substrate;
source/drain regions formed between the transistors and the isolation regions in the semiconductor substrate; and
a plurality of elements formed of insulating material being formed within the semiconductor substrate a predetermined distance beneath a top surface of the semiconductor substrate.

10. The semiconductor device of claim 9, wherein the isolation regions are partially overlapped with the plurality of elements.

11. The semiconductor device of claim 9, wherein the source/drain region is partially overlapped with the plurality of elements.

12. The semiconductor device of claim 9, wherein the elements are spaced apart periodically in a horizontal dimension.

13. The semiconductor device of claim 9, wherein the elements have a multilayered structure.

14. The semiconductor device of claim 13, wherein the elements are spaced apart periodically in a vertical dimension.

15. The semiconductor device of claim 9, wherein the elements are in a pillar shape.

16. The semiconductor device of claim 9, wherein the elements are in a grain shape.

17. The semiconductor device of claim 9, wherein the predetermined distance defines a region for forming an active region.

18. The semiconductor substrate of claim 9, wherein the elements comprise silicon oxide.

19. A method of forming a semiconductor substrate, comprising:
providing a semiconductor substrate; and
forming a plurality of elements formed of insulating material within the semiconductor substrate a predetermined distance beneath a top surface of the semiconductor substrate.

20. The method of claim 19, wherein the elements are spaced apart periodically in a horizontal dimension.

21. The method of claim 19, wherein the elements have a multilayered structure.

22. The method of claim 21, wherein the elements are spaced apart periodically in a horizontal dimension.

23. The method of claim 21, wherein the elements are spaced apart periodically in a vertical dimension.

24. The method of claim 19, wherein the elements are in a pillar shape.

25. The method of claim 19, wherein the elements are in a grain shape.

26. The method of claim 19, wherein the predetermined distance defines a region for forming an active region.

27. The method of claim 19, wherein the elements comprise silicon oxide.

28. A method of forming a semiconductor device, comprising:
forming isolation regions in a semiconductor substrate;
forming transistors on the semiconductor substrate;
forming source/drain regions between the transistors and the isolation regions in the semiconductor substrate; and
forming a plurality of elements of insulating material within the semiconductor substrate a predetermined distance beneath a top surface of the semiconductor substrate.

29. The method of claim 28, wherein the isolation regions are partially overlapped with the plurality of elements.

30. The method of claim 28, wherein the source/drain region is partially overlapped with the plurality of elements.

31. The method of claim 28, wherein the elements are spaced apart periodically in a horizontal dimension.

32. The method of claim 28, wherein the elements have a multilayered structure.

33. The semiconductor device of claim 32, wherein the elements are spaced apart periodically in a vertical dimension.

34. The method of claim 28, wherein the elements are in a pillar shape.

35. The method of claim 28, wherein the elements are in a grain shape.

36. The method of claim 28, wherein the elements comprise silicon oxide.

37. The method of claim 28, further comprising,
forming an ion implantation mask pattern on the semiconductor substrate, and
implanting ions to form the elements.
